(19) United States
(12) Patent Application Publication
(10) Pub. No.: US 2025/0089247 A1
(43) Pub. Date: Mar. 13, 2025

(54) FLOATING-GATE TYPE SPLIT-GATE FLASH MEMORY DEVICE AND MANUFACTURING METHOD THEREOF

(71) Applicant: Hua Hong Semiconductor (Wuxi) Limited, Wuxi (CN)

(72) Inventor: Zhaozhao XU, Wuxi (CN)

(21) Appl. No.: 18/557,798

(22) PCT Filed: Oct. 28, 2022
(86) PCT No.: PCT/CN2022/128196

§ 371 Date: Nov. 8, 2024

(30) Foreign Application Priority Data
Nov. 18, 2021 (CN) 202111370370.0

(51) Int. Cl. H10B 41/30; H01L 21/265; H01L 21/266; H01L 21/28; H01L 29/423; H01L 29/66; H01L 29/78; H01L 29/788

(52) U.S. Cl. CPC H10B 41/30; H01L 21/26513; H01L 21/266; H10D 30/022; H10D 30/0411; H10D 30/601; H10D 30/683; H10D 30/6892; H10D 64/035

(57) ABSTRACT

The present invention discloses a floating-gate type split-gate flash memory device and a manufacturing method thereof. A selection-gate oxide layer and a selection-gate poly layer are sequentially located on the P-type well; a hard mask layer is located on the selection-gate poly layer; a floating-gate dielectric layer is deposited on the hard mask layer; a second floating-gate poly layer is located between an interpoly ONO layer and the floating-gate dielectric layer; a second control-gate poly layer is located on the outer side of the interpoly ONO layer. In the present invention, a coupling mode of CG and FG is changed into coupling combining longitudinal coupling with transverse coupling from original longitudinal coupling; the structure of the device is continuously miniaturized along with the device; longitudinal coupling is gradually reduced; and therefore, the effects of strengthening the CG control ability and reducing electric leakage of the device are achieved.

### TECHNICAL FIELD

The present invention relates to the technical field of semiconductors, in particular to a floating-gate type split-gate flash memory device and a manufacturing method thereof.

### BACKGROUND

The split-gate floating-gate flash memory technology is widely used for applications of various embedded electronic products, such as financial IC cards and automotive electronics. With a flash memory, the memory integration density may be improved, area conservation of a chip is facilitated, and the manufacturing cost is lowered.

As shown in FIGS. 1-7, the manufacturing method for an existing 2-bit/cell split-gate floating-gate flash memory device comprises the following steps of:

step 1, forming a P-type well 101 by implantation on a P-type substrate, enabling a floating-gate oxide layer 102, a first floating-gate poly layer 103 and a first silicon nitride layer 502 to grow by thermal oxidation on the P-type well 101; forming a shallow trench 501 by a shallow-trench-isolation process; and defining active regions of a flash memory and a peripheral logical region at the same time.

Step 2, sequentially depositing an interpoly oxide-nitride-oxide (ONO) layer 104, a first control-gate poly layer 105 and a thick silicon nitride layer 504; and defining a flash memory unit region by means of photolithography, and removing the portion, at an opening region, of the thick silicon nitride layer by means of etching.

Step 3, depositing a first silicon oxide layer, and forming a first spacer dielectric layer 112 by means of anisotropic etching, wherein a width of the bottom of a spacer defines a length of a control gate.

Step 4, with the first spacer dielectric layer as a hard mask, performing anisotropic etching on control-gate poly to form a self-aligned control gate, and etching the ONO layer.

Step 5, depositing an insulating dielectric layer, forming a second spacer dielectric layer 106 by means of anisotropic etching, and forming a floating-gate through self-aligned etching with a second spacer and the first spacer as a hard mask collectively.

Step 6, sequentially depositing a selection-gate dielectric layer 107 and a selection-gate poly layer 108, and forming a self-aligned selection gate through a chemical mechanical polish (CMP) mode.

Step 7, forming silicon oxide on the selection-gate poly layer 108 by means of thermal oxidation, taking the selection-gate poly layer as a hard mask with the first spacer 112 and the selection-gate dielectric layer 107 together, removing the portions of the thick silicon nitride layer 504, the first control-gate poly layer 105, the interpoly oxide-nitride-oxide layer 104 and the first floating-gate poly layer 103 that remaining on the two sides, forming a first LDD region 110 by means of lightly doped drain (LDD) implantation, forming a third spacer dielectric layer 109 by means of deposition and etching, forming a source/drain region (i.e. a source region and a drain region) 111 by means of source/drain implantation, and then forming low-resistivity metal silicide 113 by a metal silicification process.

Whereas, discovered from further miniaturization of the floating-gate type split-gate flash memory device, due to reduction in overlapping area of a control gate (CG) and a floating gate (FG), a coupling coefficient of the CG to the FG is greatly decreased, and a coupling coefficient of a word line (WL) to the FG is rapidly increased to 24.6% from 13.7%. Due to rapid increase in the WL coupling coefficient, the turn-off ability of the CG (the control ability of the CG) of the device deteriorates, and electric leakage is very serious (a relationship curve of a current on a bit line (BL) to a voltage on the CG shows that a subthreshold swing reaches 800 mV/decade, as shown in FIG. 9). Therefore, how to increase the coupling coefficient of the CG (that is, increase the overlapping area of the CG and the FG) and reduce the coupling coefficient of the WL is very critical to further miniaturize the floating-gate type split-gate flash memory. Wherein an abscissa in FIG. 8 represents voltage of the control gate, and an ordinate in the FIG. 8 represents a current applied to the bit line.

### BRIEF SUMMARY

Aiming to the above conditions, in order to overcome the defects in the prior art, the present invention provides a floating-gate type split-gate flash memory device and a manufacturing method thereof.

In the present invention, the above technical problems are solved by the following technical solution: disclosed is a floating-gate type split-gate flash memory device, comprising a P-type well, a selection-gate oxide layer, a selection-gate poly layer, an interpoly ONO layer, a second control-gate poly layer, a hard mask layer, a floating-gate dielectric layer, a second floating-gate poly layer, a second LDD region, a fifth spacer dielectric layer, a sixth spacer dielectric layer and a source/drain region. The selection-gate oxide layer and the selection-gate poly layer are sequentially located on the P-type well; the hard mask layer is located on the selection-gate poly layer; the floating-gate dielectric layer is deposited on the hard mask layer, the selection-gate oxide layer, the selection-gate poly layer and the P-type well; the second floating-gate poly layer is located between the interpoly ONO layer and the floating-gate dielectric layer; the second control-gate poly layer is located on the outer side of the interpoly ONO layer; the second LDD region and the source/drain region are respectively located on the tops of the two sides of the P-type well; and the fifth spacer dielectric layer and the sixth spacer dielectric layer are sequentially located on the outer side of the second control-gate poly layer.

Preferably, the second control-gate poly layer and the second floating-gate poly layer are both of spacer type poly.

Preferably, the interpoly ONO layer comprises a second silicon oxide layer, a second silicon nitride layer and a third silicon oxide layer; and the second silicon nitride layer is located between the second silicon oxide layer and the third silicon oxide layer.

Preferably, the interpoly ONO layer is in a U shape.

The present invention further provides a manufacturing method for the floating-gate type split-gate flash memory device, comprising the following steps of:
step 11, forming the P-type well by implantation on a P-type substrate, and sequentially forming the selection-gate oxide layer, the selection-gate poly layer and the hard mask layer on the P-type well;
step 12, forming a fourth spacer dielectric layer by means of deposition, conducting self alignment with the spacer dielectric layer and the hard mask layer as a hard mask layer, and anisotropically etching the selection-gate oxide layer and the selection-gate poly layer in sequence;
step 13, sequentially forming the floating-gate dielectric layer and the second floating-gate poly layer by means of deposition, selectively etching the floating gate by means of photolithography to form mutually isolated floating-gate poly blocks in a width direction of the device, and then forming the interpoly ONO layer between the control gate and the floating gate by means of deposition;
step 14, forming the second control-gate poly layer by means of deposition, and anisotropically etching the second control-gate poly layer;
step 15, anisotropically etching the interpoly ONO layer between the control gate and the floating gate and the second control-gate poly layer in sequence, and forming the second LDD region by means of LDD implantation; and
step 16, forming the fifth spacer dielectric layer and the sixth spacer dielectric layer by means of deposition and etching, and forming the source/drain region by means of heavily doped source/drain implantation.

Preferably, in the step 11, a morphology of the hard mask layer is defined by means of photolithography, and a photo resist is removed.

Preferably, in the step 13, the step 14 and the step 16, the chemical vapor deposition process is employed for deposition.

The present invention has the positive effects that: a coupling mode of CG and FG is changed into coupling combining longitudinal coupling with transverse coupling from original longitudinal coupling; the structure of the device is continuously miniaturized along with the device; longitudinal coupling is gradually reduced; and transverse coupling takes a major proportion, so that an overlapping area of the CG and the FG may be increased by increasing a height of the control gate of the device, and the coupling coefficient of the CG to the FG of the device is increased. Due to transverse coupling (the overlapping area is related to the height of the CG only), the CG-FG coupling coefficient cannot be decreased with decrease in size of the device, so that miniaturization of the device is facilitated, the effects of strengthening the CG control ability and reducing electric leakage of the device are achieved, and the performance of the flash memory device is improved. The WL-FG overlapping area depends on a thickness of WL-Poly; and if the thickness of the WL-Poly is smaller than 500 A, and a height of CG-Poly is larger than 1000 A, the WL-FG coupling coefficient may be effectively decreased, and the CG-FG coupling coefficient may be increased at the same time. The second control-gate poly layer and the second floating-gate poly layer are both of the spacer type poly, so that self-aligned etching of the control gate and the floating gate may be achieved, and decrease in size of the device is facilitated.

### BRIEF DESCRIPTION OF THE DRAWINGS

FIGS. 1-7 are process step diagrams of a split-gate floating-gate flash memory device in the prior art.

FIG. 8 is a schematic diagram of a relationship curve of a current on a bit line to a voltage on a CG in the prior art.

FIGS. 9-14 are process step diagrams of a floating-gate type split-gate flash memory device of the present invention.

FIG. 15 is a schematic diagram of a relationship curve of a current on a bit line to a voltage on a CG of the present invention.

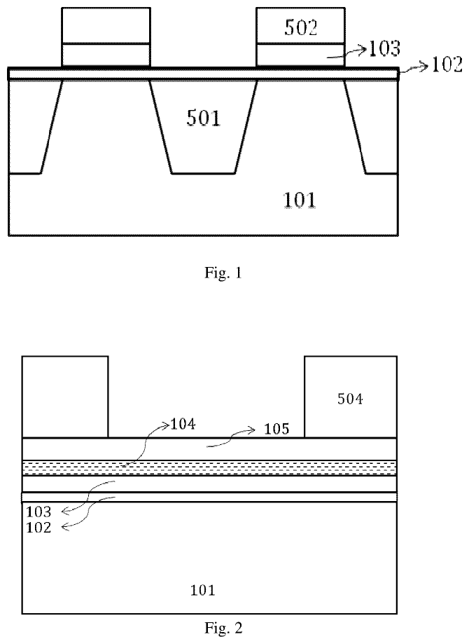

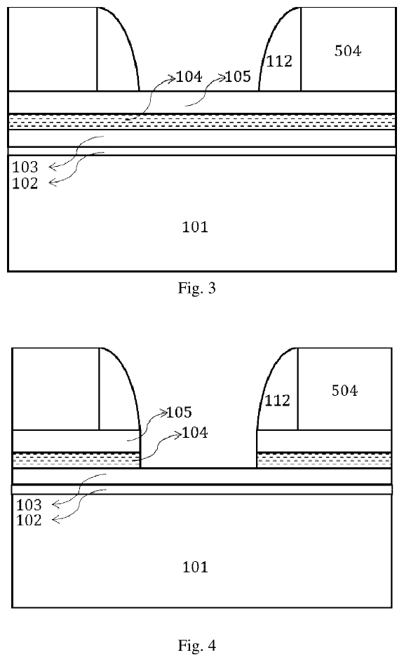

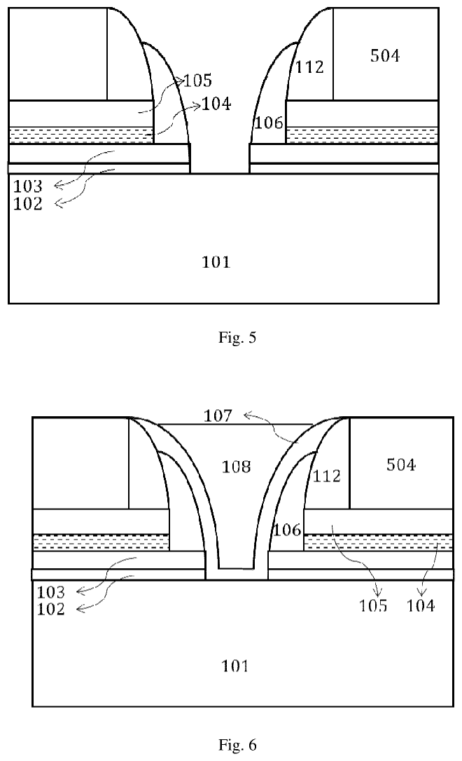

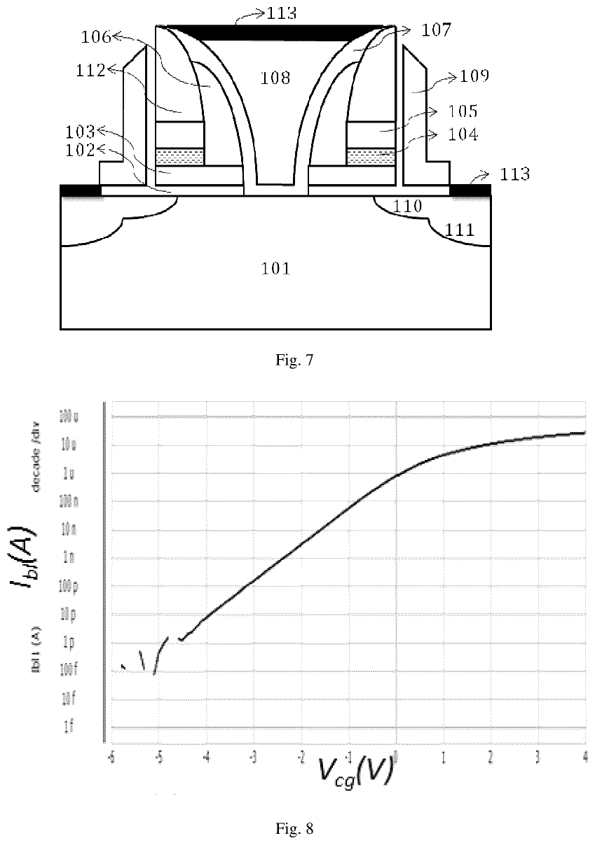

### DETAILED DESCRIPTION OF THE APPLICATOIN

The technical solutions in the embodiments of the present invention are described clearly and completely in the following with reference to accompanying drawings in the embodiments of the present invention. Apparently, the described embodiments are only part rather than all of the embodiments of the present invention.

A floating-gate type split-gate flash memory device of the present invention comprises a P-type well 101, a selection-gate oxide layer 1021, a selection-gate poly layer 1031, an interpoly ONO layer, a second control-gate poly layer 1051, a hard mask layer 1061, a floating-gate dielectric layer 1071, a second floating-gate poly layer 1081, a second LDD region 1091, a fifth spacer dielectric layer 1101, a sixth spacer dielectric layer 1102 and a source/drain region 111. The selection-gate oxide layer 1021 and the selection-gate poly layer 1031 are sequentially located on the P-type well 101; the hard mask layer 1061 is located on the selection-gate poly layer 1031; the floating-gate dielectric layer 1071 is deposited on the hard mask layer 1061, the selection-gate oxide layer 1021, the selection-gate poly layer 1031 and the P-type well 101; the second floating-gate poly layer 1081 is located between the interpoly ONO layer and the floating-gate dielectric layer 1071; the second control-gate poly layer 1051 is located on the outer side of the interpoly ONO layer; the second LDD region 1091 and the source/drain region 111 are respectively located on the tops of the two sides of the P-type well 101; and the fifth spacer dielectric layer 1101 and the sixth spacer dielectric layer 1102 are sequentially located on the outer side of the second control-gate poly layer 1051.

The second control-gate poly layer 1051 and the second floating-gate poly layer 1081 are both of spacer type poly, so that self-aligned etching of a control gate and a floating gate may be achieved, and decrease in size of the device is facilitated.

The interpoly ONO layer comprises a second silicon oxide layer 1041, a second silicon nitride layer 1042 and a third silicon oxide layer 1043, and the second silicon nitride layer 1042 is located between the second silicon oxide layer 1041 and the third silicon oxide layer 1043, so that relatively high critical electric field strength and relatively low defect density can be obtained.

The interpoly ONO layer is in a U shape, and thus the floating-gate dielectric layer 1071 and the like can be conveniently wrapped.

The floating-gate dielectric layer 1071 is made of silicon oxide.

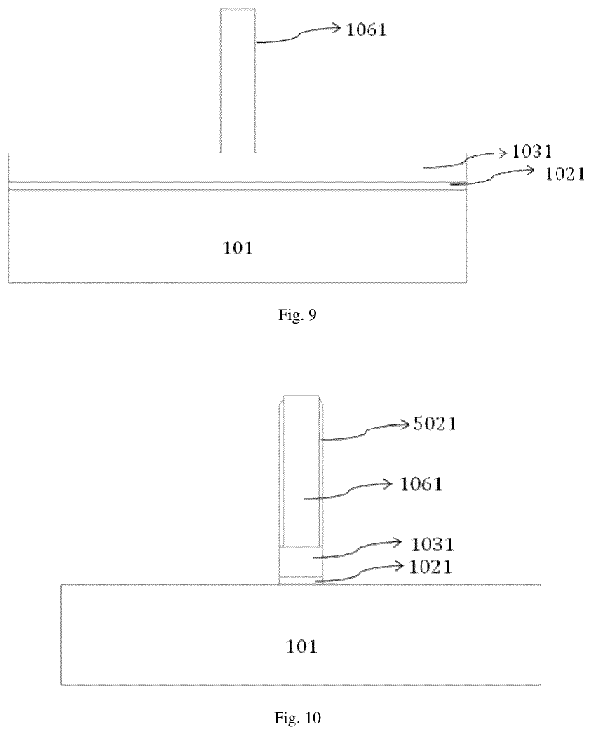

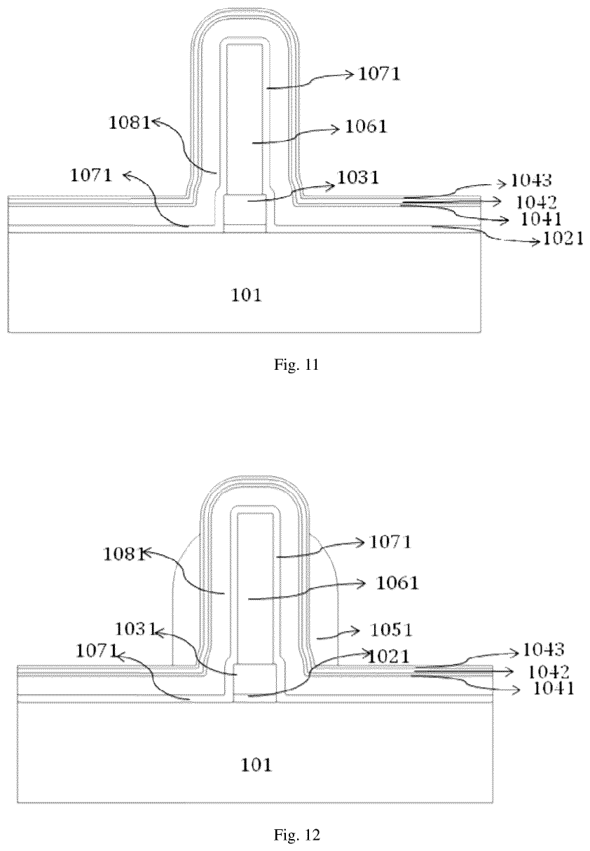

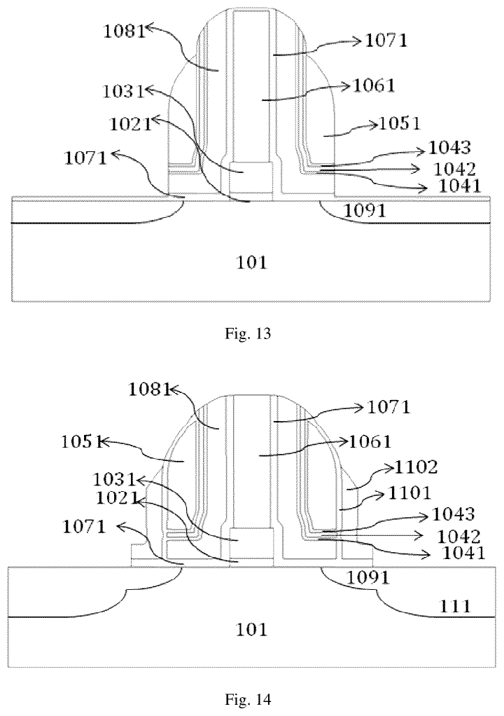

As shown in FIGS. 9-14, a manufacturing method for the floating-gate type split-gate flash memory device of the present invention comprises the following steps of:
step 11, forming a P-type well 101 by implantation on a P-type substrate, and sequentially forming the selection-gate oxide layer 1021, the selection-gate poly layer 1031 and the hard mask layer 1061 on the P-type well 101; and defining a morphology of the hard mask layer 1061 by means of photolithography, and removing a photo resist, wherein in addition to serving as a hard mask layer, the hard mask layer 1061 further serves as an isolation dielectric layer between the floating-gate layers.
step 12, forming a fourth spacer dielectric layer by means of deposition, conducting self alignment with the spacer dielectric layer and the hard mask layer as a hard mask layer, and anisotropically etching the selection-gate oxide layer and the selection-gate poly layer in sequence;
step 13, sequentially forming the floating-gate dielectric layer 1071 and the second floating-gate poly layer 1081 by means of deposition, selectively etching the floating gate by means of photolithography to form mutually isolated floating-gate poly blocks in a width direction of the device, and then forming the interpoly ONO layer between the control gate and the floating gate by means of deposition;
step 14, forming the second control-gate poly layer 1051 by means of deposition, and anisotropically etching the second control-gate poly layer 1051;
step 15, anisotropically etching the interpoly ONO layer between the control gate and the floating gate and the second control-gate poly layer 1081 in sequence, and forming the second LDD region by means of LDD implantation 1091; and
step 16, forming the fifth spacer dielectric layer 1101 and the sixth spacer dielectric layer 1102 by means of deposition and etching, and forming the source/drain region by means of heavily doped source/drain implantation 111.

The interpoly ONO layer comprises a second silicon oxide layer 1041, a second silicon nitride layer 1042 and a third silicon oxide layer 1043, and the second silicon nitride layer 1042 is located between the second silicon oxide layer 1041 and the third silicon oxide layer 1043, so that relatively high critical electric field strength and relatively low defect density can be obtained.

In the step 13, the step 14 and the step 16, the chemical vapor deposition process is employed for deposition, and thus the density and the purity of a coating may be controlled.

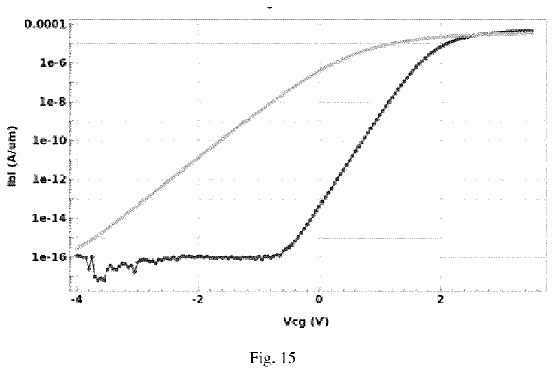

From FIG. 15, it is a relationship curve in the prior art on the upper lateral side, and it is a relationship curve of the present invention on the lower lateral side, in which an effective overlapping area of a WL and an FG is substantially unchanged while an overlapping area of a CG and the FG is increased; and without changing any implantation condition, the sub-threshold slope is reduced by 50%. Due to a great increase in coupling area of the control gate (CG), a leakage current Ir01 is lowered by more than 7 orders of magnitude or above, and a read current Ir10 is further increased by 50% at the same time, so that a window of the read current of the memory device is greatly enlarged.

To sum up, a coupling mode of the CG and FG is changed into coupling combining longitudinal coupling with transverse coupling from original longitudinal coupling; the structure of the device is continuously miniaturized along with the device; longitudinal coupling is gradually reduced; and transverse coupling takes a major proportion, so that an overlapping area of the CG and the FG may be increased by increasing a height of the control gate of the device, and the coupling coefficient of the CG to the FG of the device is increased. Due to transverse coupling (the overlapping area is related to the height of the CG only), the CG-FG coupling coefficient cannot be decreased with decrease in size of the device, so that miniaturization of the device is facilitated, the effects of strengthening the CG control ability and reducing electric leakage of the device are achieved, and the performance of the flash memory device is improved. The WL-FG overlapping area depends on a thickness of WL-Poly; and if the thickness of the WL-Poly is smaller than 500 A, and a height of CG-Poly is larger than 1000 A, the WL-FG coupling coefficient may be effectively decreased, and the CG-FG coupling coefficient may be increased at the same time. The second control-gate poly layer and the second floating-gate poly layer are both of the spacer type poly, so that self-aligned etching of the control gate and the floating gate may be achieved, and decrease in size of the device is facilitated.

The above specific embodiments are preferred embodiments of the present invention and cannot limit the present invention. Any other changes, without departing from the technical solution of the present invention, or other equivalent displacements are all included within the protection scope of the present invention.

1. A floating-gate type split-gate flash memory device, comprising a P-type well, a selection-gate oxide layer, a selection-gate poly layer, an interpoly ONO layer, a second control-gate poly layer, a hard mask layer, a floating-gate dielectric layer, a second floating-gate poly layer, a second LDD region, a fifth spacer dielectric layer, a sixth spacer dielectric layer and a source/drain region, the selection-gate oxide layer and the selection-gate poly layer being sequentially located on the P-type well, the hard mask layer being located on the selection-gate poly layer, the floating-gate dielectric layer being deposited on the hard mask layer, the selection-gate oxide layer, the selection-gate poly layer and the P-type well, the second floating-gate poly layer being located between the interpoly ONO layer and the floating-gate dielectric layer, the second control-gate poly layer being located on the outer side of the interpoly ONO layer, the second LDD region and the source/drain region being respectively located on the tops of the two sides of the P-type well, and the fifth spacer dielectric layer and the sixth spacer dielectric layer being sequentially located on the outer side of the second control-gate poly layer.

2. The floating-gate type split-gate flash memory device according to claim 1, wherein the second control-gate poly layer and the second floating-gate poly layer are both of spacer type poly.

3. The floating-gate type split-gate flash memory device according to claim 1, wherein the interpoly ONO layer comprises a second silicon oxide layer, a second silicon nitride layer and a third silicon oxide layer, the second silicon nitride layer being located between the second silicon oxide layer and the third silicon oxide layer.

4. The floating-gate type split-gate flash memory device according to claim 1, wherein the interpoly ONO layer is in a U shape.

5. The floating-gate type split-gate flash memory device according to claim 1, wherein the floating-gate dielectric layer is made of silicon oxide.

6. A manufacturing method for the floating-gate type split-gate flash memory device, comprising the following steps of:
step 11, forming the P-type well by implantation on a P-type substrate, and sequentially forming the selection-gate oxide layer, the selection-gate poly layer and the hard mask layer on the P-type well;
step 12, forming a fourth spacer dielectric layer by means of deposition, conducting self alignment with the spacer dielectric layer and the hard mask layer as a hard mask layer, and anisotropically etching the selection-gate oxide layer and the selection-gate poly layer in sequence;
step 13, sequentially forming the floating-gate dielectric layer and the second floating-gate poly layer by means of deposition, selectively etching the floating gate by means of photolithography to form mutually isolated floating-gate poly blocks in a width direction of the device, and then forming the interpoly ONO layer between the control gate and the floating gate by means of deposition;
step 14, forming the second control-gate poly layer by means of deposition, and anisotropically etching the second control-gate poly layer;
step 15, anisotropically etching the interpoly ONO layer between the control gate and the floating gate and the second control-gate poly layer in sequence, and forming the second LDD region by means of LDD implantation; and
step 16, forming the fifth spacer dielectric layer and the sixth spacer dielectric layer by means of deposition and etching, and forming the source/drain region by means of heavily doped source/drain implantation.

7. The manufacturing method for the floating-gate type split-gate flash memory device according to claim 6, wherein in the step 11, a morphology of the hard mask layer is defined by means of photolithography, and a photo resist is removed.

8. The manufacturing method for the floating-gate type split-gate flash memory device according to claim 6, wherein in the step 13, the step 14 and the step 16, the chemical vapor deposition process is employed for deposition.
